(19) United States
(12) Patent Application Publication
(10) Pub. No.: US 2025/0197999 A1
(43) Pub. Date: Jun. 19, 2025

(54) METHODS AND APPARATUS FOR GAS DISTRIBUTION

(71) Applicant: ASM IP Holding B.V., Almere (NL)

(72) Inventors: Hannelore Azora Hemminger, Tempe, AZ (US); Steven Bopp, Chandler, AZ (US)

(21) Appl. No.: 18/976,462

(22) Filed: Dec. 11, 2024

Related U.S. Application Data
(60) Provisional application No. 63/611,071, filed on Dec. 15, 2023.

(51) Int. Cl. C23C 16/455

(52) U.S. Cl. CPC C23C 16/45565

(57) ABSTRACT

Various embodiments of the present technology may provide a 3D lattice structure having a first plenum having a first volume, and a second plenum, having a second volume, isolated from the first plenum. A continuous interior wall separates the first plenum from the second plenum and an outer surface partially encloses the first and second plenums.

### CROSS-REFERENCE TO RELATED APPLICATIONS

This application is a nonprovisional of, and claims priority to and the benefit of, U.S. Provisional Patent Application No. 63/611,071, filed Dec. 15, 2023 and entitled “METHODS AND APPARATUS FOR GAS DISTRIBUTION,” which is hereby incorporated by reference herein.

### FIELD OF INVENTION

The present disclosure generally relates to a method and apparatus for gas distribution. More particularly, the present disclosure relates to a gas distribution apparatus having an internal gyroid structure.

### BACKGROUND OF THE TECHNOLOGY

Some reaction chambers used in semiconductor manufacturing utilize a gas distribution plate (sometimes referred to as a showerhead) to deliver various gases, such as a precursor and a reactant, to a substrate and form a film on the substrate. Conventional gas distribution plates provide the precursor and reactant in sequence through a shared set of through-holes in the gas distribution plate. In some cases, it may be advantageous to deliver the precursor and reactant into the reaction chamber through separate plenums.

### SUMMARY OF THE INVENTION

Various embodiments of the present technology may provide a 3D lattice structure having a first plenum having a first volume, and a second plenum, having a second volume, isolated from the first plenum. A continuous interior wall separates the first plenum from the second plenum and an outer surface partially encloses the first and second plenums.

According to one aspect, an apparatus comprises: a 3D lattice structure comprising: a first plenum having a first volume; a second plenum, having a second volume, isolated from the first plenum; and a continuous interior wall separating the first plenum from the second plenum; a first inlet coupled to the first plenum; a second inlet coupled to the second plenum; and an outer surface partially enclosing the first and second plenums.

In one embodiment, the lattice structure is triply periodic minimal surface structure.

In one embodiment, the first and second volumes are equal.

In one embodiment, the first and second volumes are not equal.

In one embodiment, the first plenum comprises a first plurality of continuous interconnected channels.

In one embodiment, the first inlet is coupled to a first channel from the first plurality of channels, and the first channel has a first width.

In one embodiment, a second channel from the first plurality of channels has a second width that is greater than the first width.

In one embodiment, the second plenum comprises a second plurality of continuous interconnected channels.

In one embodiment, the second inlet is coupled to a first channel from the second plurality of channels, and the first channel has a first width.

In one embodiment, a second channel from the second plurality of channels has a second width that is greater than the first width.

In one embodiment, the first plurality of channels are intertwined with the second plurality of channels.

In one embodiment, the first plurality of channels are coupled to the first inlet.

In one embodiment, the second plurality of channels are coupled to the second inlet.

In one embodiment, the first plurality of channels are non-linear.

According to another aspect, an apparatus comprises: a lattice structure comprising: a first plenum having a first volume and comprising a first plurality of continuous interconnected channels; a second plenum having a second volume and comprising a second plurality of continuous interconnected channels; wherein the first plurality of channels are intertwined with the second plurality of channels, and the first plurality of channels and the second plurality of channels are separated from each other by a shared interior wall; a first inlet coupled to the first plenum; a second inlet coupled to the second plenum; and an outer surface partially enclosing the first and second plenums.

In one embodiment, the first inlet is coupled to a first channel from the first plurality of channels, and the first channel has a first width.

In one embodiment, a second channel from the first plurality of channels has a second width that is greater than the first width.

In one embodiment, the second inlet is coupled to a first channel from the second plurality of channels, and the first channel has a first width.

In yet another aspect, a system comprises: a reaction chamber comprising: a susceptor configured to support a substrate; and a gas distribution system arranged above the susceptor and comprising: a first plenum comprising a first plurality of channels, wherein the first plurality of channels comprises a first channel having a first width and a second channel having a second width, wherein the second width is greater than the first width; and a second plenum, isolated from the first plenum, and comprising a second plurality of channels, wherein the second plurality of channels comprises a third channel having a third width and a fourth channel having a fourth width, wherein the fourth width is greater than the third width; a first inlet coupled to the first channel; a second inlet coupled to the third channel; a first vessel configured to contain a precursor, wherein the first vessel is coupled to the first inlet; and a second vessel configured to contain a reactant, wherein the first vessel is coupled to the second inlet.

In one embodiment, the first plurality of channels are intertwined with the second plurality of channels, and the first plurality of channels and the second plurality of channels are separated from each other by a shared interior wall.

### BRIEF DESCRIPTION OF THE DRAWING FIGURES

A more complete understanding of the present technology may be derived by referring to the detailed description when considered in connection with the following illustrative figures. In the following figures, like reference numbers refer to similar elements and steps throughout the figures.

FIG. 1 representatively illustrates a system in accordance with embodiments of the present technology;

FIG. 2 is a perspective view of a gyroid in accordance with embodiments of the present technology;

FIG. 3 is a top view of the gyroid in accordance with embodiments of the present technology;

FIG. 4 is a first side view of the gyroid in accordance with embodiments of the present technology;

FIG. 5 is a second side view in accordance with embodiments of the present technology;

FIG. 6 representatively illustrates inverse plenums of the gyroid in accordance with embodiments of the present technology;

FIG. 7 representatively illustrates a unit cell of a gyroid in accordance with embodiments of the present technology;

FIG. 8 representatively illustrates a network of connected gyroid cells in accordance with embodiments of the present technology;

FIG. 9 representatively illustrates a portion of the gyroid network in accordance with embodiments of the present technology;

FIG. 10 is an orthographic projection of a gyroid in accordance with embodiments of the present technology;

FIG. 11 is a top view of the gyroid of FIG. 10; and

FIG. 12 representatively illustrates a cross-sectional view of channels of a gyroid structure in accordance with embodiments of the present technology.

### DETAILED DESCRIPTION OF EXEMPLARY EMBODIMENTS

The present technology may be described in terms of functional block components and various processing steps. Such functional blocks may be realized by any number of components configured to perform the specified functions and achieve the various results. For example, the present technology may employ various gas lines, valves, power supply, pressure controllers, and filters.

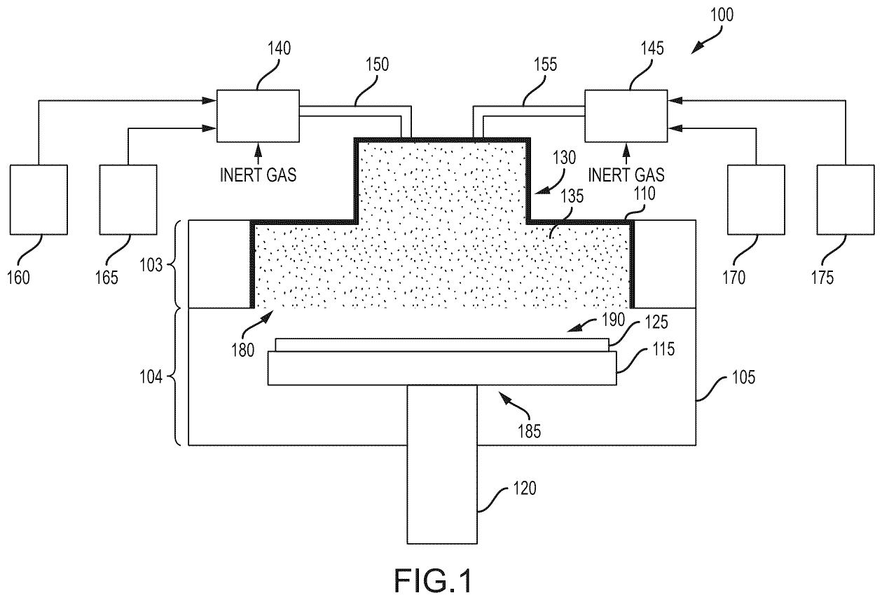

Referring to FIG. 1, an exemplary system 100 may comprise a reactor 105 comprising an upper body 103 and a lower body 104. The upper body 103 and the lower body 104 may be connected to each other. In more detail, the upper body 103 and the lower body 104 of the reactor 105 may form a reaction space 190 while face-contacting and face-sealing each other.

In various embodiments, the reactor 105 may be configured to perform processing on an object to be processed, such as a substrate 125 (e.g., a wafer). For example, the reactor 105 may be configured to perform heating, deposition, etching, polishing, ion implantation, and/or other processing on the object to be processed. In some embodiments, the reactor 105 may be configured to perform a movement function, a vacuum sealing function, a heating function, an exhaust function, and/or other functions for the object to be processed such that the object is processed in the reactor. In some embodiments, the reactor 105 may be a reactor in which an atomic layer deposition (ALD) or a chemical vapor deposition (CVD) process is performed.

In various embodiments, the reactor 105 may include, in the reaction space 190, a substrate mounting unit 185. The substrate mounting unit 185 may comprise a susceptor 115 for supporting the substrate 125 and a heater (not shown) for heating the substrate supported by the susceptor 115. The heater may be embedded within the susceptor 115. The substrate mounting unit 185 may further comprise a pedestal 120 to support the susceptor 115. For loading/unloading of the substrate, the substrate mounting unit 185 may be configured to be vertically movable by being connected to a driving unit (not shown).

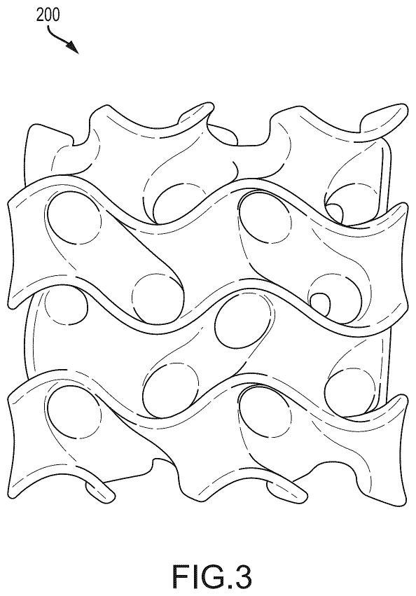

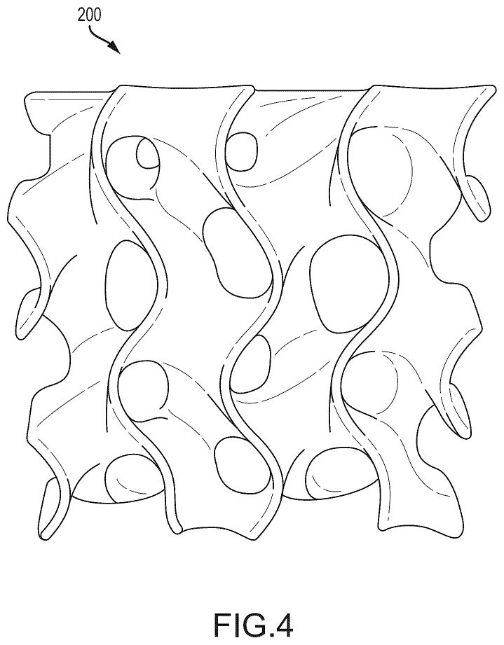

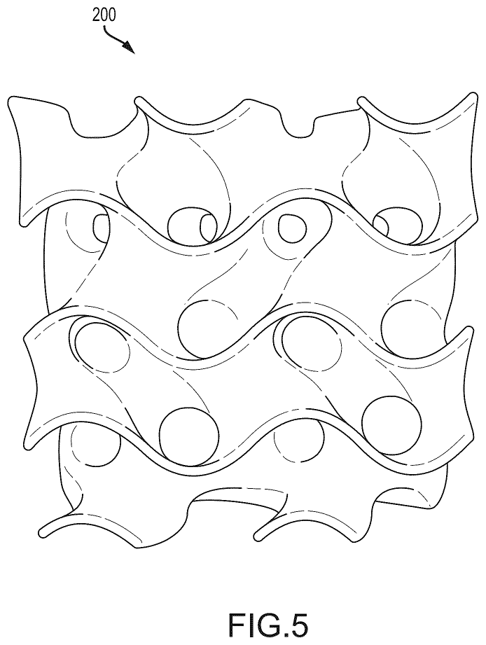

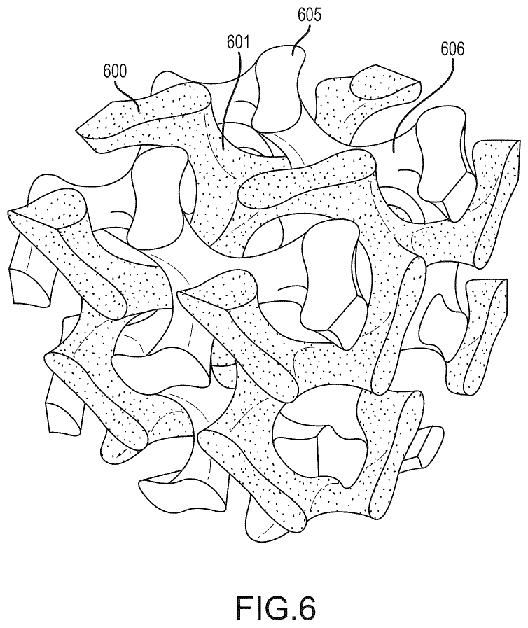

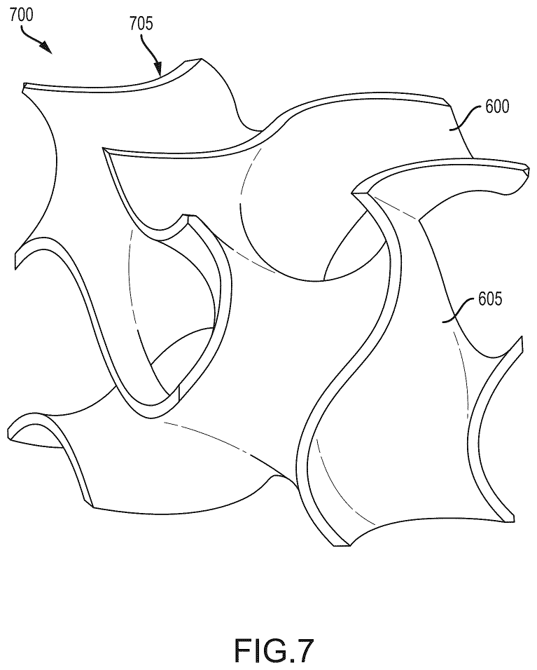

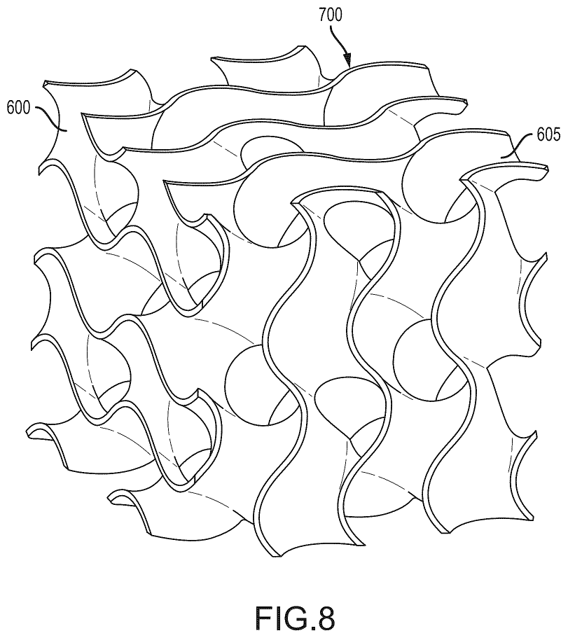

In various embodiments, and referring to FIGS. 1-8, the upper body 103 may comprise a gas distribution system 110 (i.e., a showerhead). The gas distribution system 110 may comprise a 3D lattice structure 200 comprising a first plenum 600 and a second plenum 605. It should be noted that for illustrative purposes only, FIG. 6 shows the inverse of plenums 600, 605. The 3D lattice structure may be a triply period minimal surface structure, for example a gyroid structure or any other structure having two or more separate plenums. The 3D lattice structure may be formed from a plurality of unit cells, where FIG. 7 illustrates a single unit cell having the first plenum 600 and the second plenum 605.

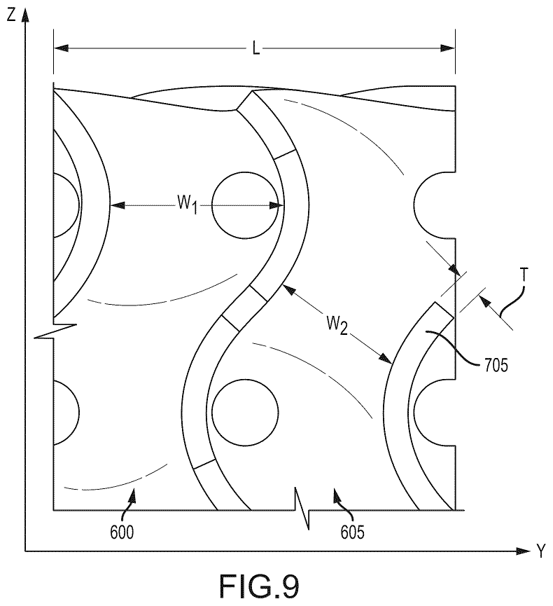

A continuous interior wall 705 separates the first plenum 600 from the second plenum 605. In other words, the first plenum 600 is isolated from the second plenum 605 by the continuous interior wall 705. The continuous interior wall 705 has a thickness T (FIG. 9). The continuous interior wall 705 may have a smooth or polished surface facing into the plenums.

The gas distribution system 110 may further comprise an outer surface wall 130 that partially encloses or otherwise bounds the first and second plenums 600, 605. For example, the first and second plenums 600, 605 may be open to the reaction space 190 at a surface plane 180 that is directly above the susceptor 115 and substrate 125. In other words, the outer surface wall 130 may enclose all but the surface plane 180 of the triply period minimal surface structure.

In various embodiments, the first plenum 600 has a first volume and the second plenum 605 has a second volume. In some embodiments, the first volume may be equal to the second volume. Alternatively, the first volume may be different from (larger or smaller) the second volume.

In various embodiments, the first plenum 600 may comprise a first plurality of continuous interconnected channels 601 forming the first volume. The first plurality of channels 601 may be branched (i.e., non-linear), for example, two or more channels 601 may connect at a first node. The first plurality of channels 601 may have a first width W₁.

Similarly, the second plenum 605 may comprise a second plurality of continuous interconnected channels 606 forming the second volume. The second plurality of channels 606 may be branched, for example, two or more channels 606 may connect at a second node. The second plurality of channels 606 may have a second width W₂.

In various embodiments, the first plurality of channels 600 are intertwined with the second plurality of channels 606.

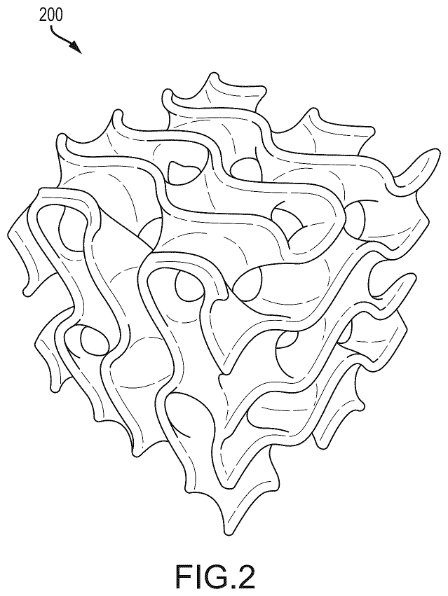

As described above, the volume of the first plenum 600 may be the same as the volume of the second plenum 605. In such a case, the first width W₁ will be equal to the second width W₂. FIGS. 2-8 illustrate a gyroid structure where the first plenum 600 has the same volume as the second plenum 605.

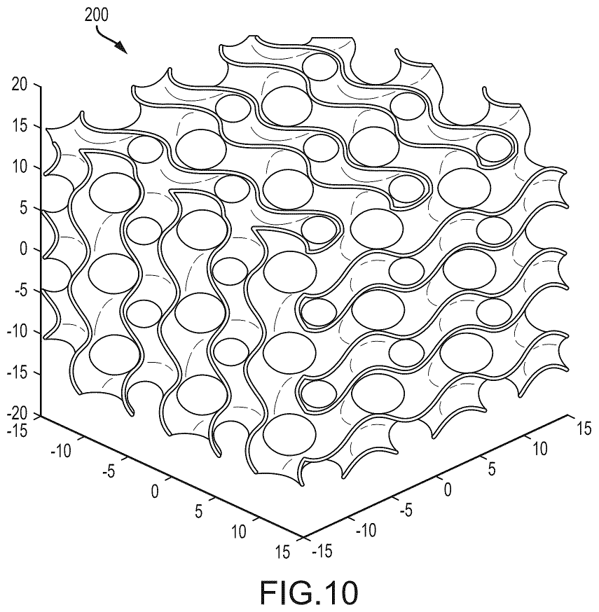

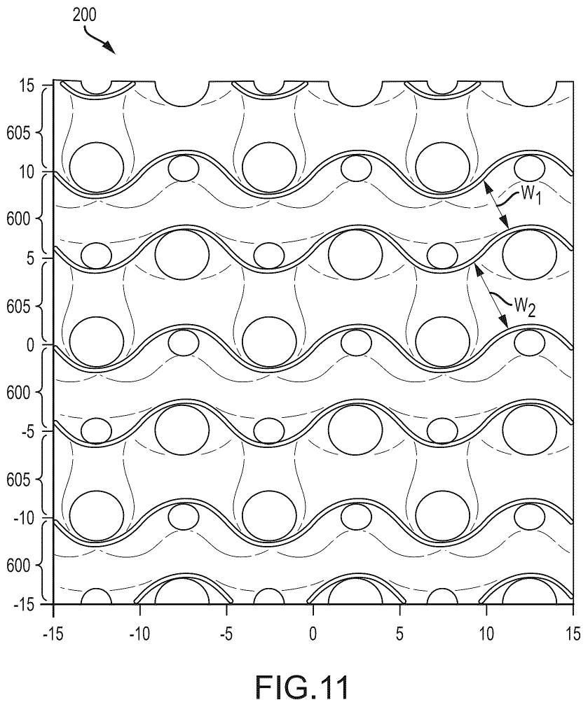

Alternatively, FIGS. 10-11 illustrate a gyroid structure where the first plenum 600 has a first width Wi that is less than the second width W₂ of the second plenum 605. Accordingly, the volume of the first plenum 600 is less than the volume of the second plenum 605. The gyroid structure may be described as having an aspect ratio of W₁/W₂.

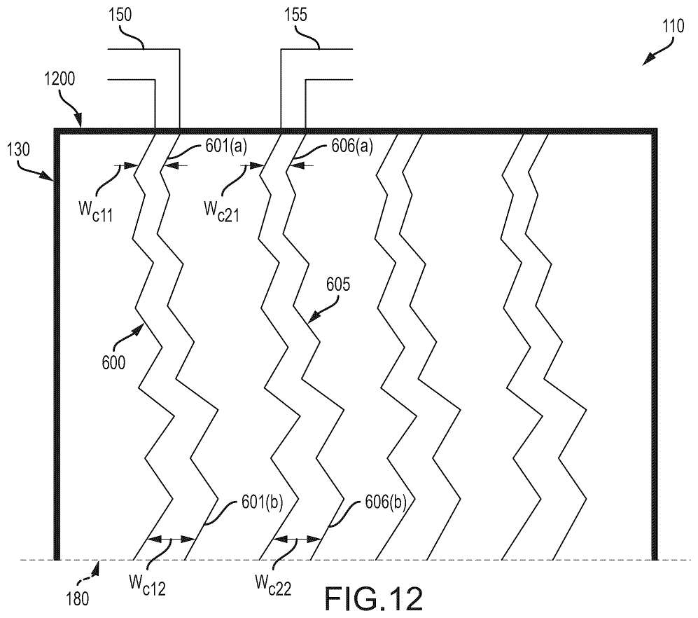

In various embodiments, and referring to FIG. 12, the channels within each plenum may vary in width from a top 1200 of the outer surface 130 to the surface plane 180.

In some embodiments, the first plurality of channels 601 may have a variable width. For example, a first channel 601(a) from the first plurality of channels 601 may have a first width W_{C11} and a second channel 601(b) from the first plurality of channels 601 may have a second width W_{C12} that is greater than the first width W_{V1}. In other words, the width of the channels 601 increases from the top 1200 to the surface plane 180.

Similarly, the second plurality of channels 606 may have a variable width. For example, a first channel 606(a) from the second plurality of channels 606 may have a first width W_{C21} and a second channel 606(b) from the first plurality of channels 606 may have a second width W_{C22} that is greater than the first width W_{C21}. In other words, the width of the channels 606 increases from the top 1200 to the surface plane 180.

Additionally or alternatively, the width of the channels 601, 606 at the surface plane 180 may vary. For example, channels at or near the center of the gas distribution system 110 and along the surface plane 180 may be narrower than channels at the edge of the gas distribution system 110. The present embodiment may also be combined with the embodiment of FIG. 12.

In various embodiments, the size of the cells, wall thickness, and channel widths may vary throughout a single feature. For example, in a single feature, there may be areas that have smaller cell sizes to provide a higher density area and other areas with larger cell sizes to provide a lower density area. The density of the area may correspond to improved heat transfer or temperature modulation. Accordingly, some areas of a feature may be designed to provide a particular temperature profile by having some areas with higher density cells and other areas with lower density cells.

In various embodiments, the gas distribution system 110 may be formed from a metal such as stainless steel, aluminum, a metal alloy, or the like, by additive manufacturing (i.e., 3D printing) or any other suitable manufacturing process.

In various embodiments, and referring back to FIG. 1, the system 100 may further comprise a plurality of valve manifolds, such as a first valve manifold 140 and a second valve manifold 145, coupled to the gas distribution system 100. The first valve manifold 140 may comprise a plurality of inlets and an outlet. The outlet of the first valve manifold 140 may be coupled to the first plenum 600 via a first gas line 150. Similarly, the second valve manifold 145 may comprise a plurality of inlets and an outlet. The outlet of the second valve manifold 145 may be coupled to the second plenum 605 via a second gas line. For example, the first gas line 150 may be coupled directly to a channel from the first plenum 600 and the second gas line 155 may be coupled directly to a channel from the second plenum 605.

In various embodiments, the system 100 may further comprise a plurality of vessels, wherein each vessel contain a different chemistry. For example, the system 100 may comprise a first vessel 160 configured to contain a first chemistry and a second vessel 165 configured to contain a second chemistry. Each of the first and second vessels 160, 165 may be coupled to one of the inlets of the first valve manifold 140 via gas lines. Accordingly, the first and second vessels 160, 165 may supply the first and second chemistry to the first plenum 600.

Similarly, the system 100 may comprise a third vessel 170 configured to contain a third chemistry and a fourth vessel 175 configured to contain a fourth chemistry. Each of the third and fourth vessels 170, 175 may be coupled to one of the inlets of the second valve manifold 145 via gas lines. Accordingly, the third and fourth vessels 170, 175 may supply the third and fourth chemistry to the second plenum 605.

In various embodiments, an inlet of the first valve manifold 140 may be coupled to an inert gas and an inlet of the second valve manifold 145 may be coupled to the inert gas.

In various embodiments, the system 100 may also comprise a controller (not shown) and a plurality of valves (not shown) disposed within the gas lines, such as gas lines 150, 155 and the gas lines from the vessels 160, 165, 170, 175 to the valve manifolds 140, 145. The controller may operate the valves to provide the various chemistries to the gas distribution system 110 according to a desired pulsing scheme.

In various embodiments, other components of the system may be formed using 3-D printing to form the gyroid structure, such as insulation layers, valves, gas lines, showerhead, chamber body, and the like.

In operation, the controller may open a valve to flow the first chemistry through the first valve manifold 140 to the first plenum 600. At the same time, the inert gas may flow through the first valve manifold 140 and into the first plenum. In addition, at the same time, the inert gas may be flowed through the second valve manifold 145 and into the second plenum 605.

Advantages of the present invention may include lower chemistry use due to less surface area on the interior walls compared to conventional systems, less frequent cleaning of the interior walls, and/or easier cleaning of the interior walls.

In the foregoing description, the technology has been described with reference to specific exemplary embodiments. The particular implementations shown and described are illustrative of the technology and its best mode and are not intended to otherwise limit the scope of the present technology in any way. Indeed, for the sake of brevity, conventional manufacturing, connection, preparation, and other functional aspects of the method and system may not be described in detail. Furthermore, the connecting lines shown in the various figures are intended to represent exemplary functional relationships and/or steps between the various elements. Many alternative or additional functional relationships or physical connections may be present in a practical system.

The technology has been described with reference to specific exemplary embodiments. Various modifications and changes, however, may be made without departing from the scope of the present technology. The description and figures are to be regarded in an illustrative manner, rather than a restrictive one and all such modifications are intended to be included within the scope of the present technology. Accordingly, the scope of the technology should be determined by the generic embodiments described and their legal equivalents rather than by merely the specific examples described above. For example, the steps recited in any method or process embodiment may be executed in any order, unless otherwise expressly specified, and are not limited to the explicit order presented in the specific examples. Additionally, the components and/or elements recited in any apparatus embodiment may be assembled or otherwise operationally configured in a variety of permutations to produce substantially the same result as the present technology and are accordingly not limited to the specific configuration recited in the specific examples.

Benefits, other advantages and solutions to problems have been described above with regard to particular embodiments. Any benefit, advantage, solution to problems or any element that may cause any particular benefit, advantage or solution to occur or to become more pronounced, however, is not to be construed as a critical, required or essential feature or component.

The terms “comprises”, “comprising”, or any variation thereof, are intended to reference a non-exclusive inclusion, such that a process, method, article, composition or apparatus that comprises a list of elements does not include only those elements recited, but may also include other elements not expressly listed or inherent to such process, method, article, composition or apparatus. Other combinations and/or modifications of the above-described structures, arrangements, applications, proportions, elements, materials or components used in the practice of the present technology, in addition to those not specifically recited, may be varied or otherwise particularly adapted to specific environments, manufacturing specifications, design parameters or other operating requirements without departing from the general principles of the same.

The present technology has been described above with reference to an exemplary embodiment. However, changes and modifications may be made to the exemplary embodiment without departing from the scope of the present technology. These and other changes or modifications are intended to be included within the scope of the present technology, as expressed in the following claims.

What is claimed is:

1. An apparatus, comprising:
a 3D lattice structure comprising:
a first plenum having a first volume;
a second plenum, having a second volume, isolated from the first plenum; and
a continuous interior wall separating the first plenum from the second plenum;
a first inlet coupled to the first plenum;
a second inlet coupled to the second plenum; and
an outer surface partially enclosing the first and second plenums.

2. The apparatus according to claim 1, wherein the lattice structure is triply periodic minimal surface structure.

3. The apparatus according to claim 1, wherein the first and second volumes are equal.

4. The apparatus according to claim 1, wherein the first and second volumes are not equal.

5. The apparatus according to claim 1, wherein the first plenum comprises a first plurality of continuous interconnected channels.

6. The apparatus according to claim 5, wherein the first inlet is coupled to a first channel from the first plurality of channels, and the first channel has a first width.

7. The apparatus according to claim 6, wherein a second channel from the first plurality of channels has a second width that is greater than the first width.

8. The apparatus according to claim 1, wherein the second plenum comprises a second plurality of continuous interconnected channels.

9. The apparatus according to claim 8, wherein the second inlet is coupled to a first channel from the second plurality of channels, and the first channel has a first width.

10. The apparatus according to claim 9, wherein a second channel from the second plurality of channels has a second width that is greater than the first width.

11. The apparatus according to claim 1, wherein the first plurality of channels are intertwined with the second plurality of channels.

12. The apparatus according to claim 1, wherein the first plurality of channels are coupled to the first inlet.

13. The apparatus according to claim 1, wherein the second plurality of channels are coupled to the second inlet.

14. The apparatus according to claim 5, wherein the first plurality of channels are non-linear.

15. An apparatus, comprising:
a lattice structure comprising:
a first plenum having a first volume and comprising a first plurality of continuous interconnected channels;
a second plenum having a second volume and comprising a second plurality of continuous interconnected channels;
wherein the first plurality of channels are intertwined with the second plurality of channels, and the first plurality of channels and the second plurality of channels are separated from each other by a shared interior wall;
a first inlet coupled to the first plenum;
a second inlet coupled to the second plenum; and
an outer surface partially enclosing the first and second plenums.

16. The system according to claim 15, wherein the first inlet is coupled to a first channel from the first plurality of channels, and the first channel has a first width.

17. The system according to claim 16, wherein a second channel from the first plurality of channels has a second width that is greater than the first width.

18. The system according to claim 15, wherein the second inlet is coupled to a first channel from the second plurality of channels, and the first channel has a first width.

19. A system, comprising:
a reaction chamber comprising:
a susceptor configured to support a substrate; and
a gas distribution system arranged above the susceptor and comprising:
a first plenum comprising a first plurality of channels, wherein the first plurality of channels comprises a first channel having a first width and a second channel having a second width, wherein the second width is greater than the first width; and
a second plenum, isolated from the first plenum, and comprising a second plurality of channels, wherein the second plurality of channels comprises a third channel having a third width and a fourth channel having a fourth width, wherein the fourth width is greater than the third width;
a first inlet coupled to the first channel;
a second inlet coupled to the third channel;
a first vessel configured to contain a precursor, wherein the first vessel is coupled to the first inlet; and
a second vessel configured to contain a reactant, wherein the first vessel is coupled to the second inlet.

20. The system according to claim 19, wherein the first plurality of channels are intertwined with the second plurality of channels, and the first plurality of channels and the second plurality of channels are separated from each other by a shared interior wall.
